(19) United States
(12) Patent Application Publication
(10) Pub. No.: US 2016/0064059 A1
(43) Pub. Date: Mar. 3, 2016

(54) SEMICONDUCTOR MEMORY DEVICE

(71) Applicant: Masahiro TAKAHASHI, Seongnam-si (KR)

(72) Inventor: Masahiro TAKAHASHI, Seongnam-si (KR)

(21) Appl. No.: 14/627,592

(22) Filed: Feb. 20, 2015

Related U.S. Application Data
(60) Provisional application No. 62/044,734, filed on Sep. 2, 2014.

(51) Int. Cl. G11C 11/16

(52) U.S. Cl. CPC G11C 11/1675; G11C 11/1673; G11C 11/1697; G11C 11/1693

(57) ABSTRACT

According to one embodiment, a semiconductor memory device comprises a memory cell including a variable resistance element, a sense amplifier connected to one side of the memory cell, and a write driver connected to the other side of the memory cell. A write current flows between the sense amplifier and the write driver in a write operation.

### CROSS REFERENCE TO RELATED APPLICATIONS

This application is based upon and claims the benefit of priority from U.S. Provisional Application No. 62/044,734, filed Sep. 2, 2014, the entire contents of all of which are incorporated herein by reference.

### FIELD

Embodiments described herein relate generally to a semiconductor memory device.

### BACKGROUND

Recently, a semiconductor memory using a variable resistance element as a memory element is attracting attention.

For example, a magnetoresistive element called an MTJ (Magnetic Tunnel Junction) element is used as a memory element in an MRAM (Magnetic Random Access Memory). The MTJ element includes a reference layer in which the magnetization direction is fixed, a memory layer in which the magnetization direction can freely be reversed, and a tunnel barrier layer sandwiched between the reference layer and memory layer. The MTJ element uses a resistance change called a magnetoresistive effect, which is caused by a relative magnetization direction in the memory layer with respect to the reference layer. That is, data “1” or “0” is discriminated by using a resistance difference produced by these relative magnetization directions.

### BRIEF DESCRIPTION OF THE DRAWINGS

FIG. 1 is a schematic view showing the arrangement of a semiconductor memory device according to the first embodiment;

FIG. 2A is a sectional view showing an outline of the arrangement of a variable resistance element;

FIG. 2B is a sectional view for explaining a write operation of the variable resistance element (magnetoresistive element) in a parallel state;

FIG. 2C is a sectional view for explaining a write operation of the variable resistance element (magnetoresistive element) in an antiparallel state;

FIG. 3 is a schematic view showing each constituent element according to the first embodiment;

FIG. 4 is a timing chart showing a read operation of the semiconductor memory device according to the first embodiment;

FIG. 5 is a schematic view showing the read operation at time T11 of the semiconductor memory device according to the first embodiment;

FIG. 6 is a schematic view showing the read operation at time T12 of the semiconductor memory device according to the first embodiment;

FIG. 7 is a schematic view showing the read operation at time T13 of the semiconductor memory device according to the first embodiment;

FIG. 8 is a timing chart showing a “1” write operation of the semiconductor memory device according to the first embodiment;

FIG. 9 is a schematic view showing the “1” write operation of the semiconductor memory device according to the first embodiment;

FIG. 10 is a timing chart showing a “0” write operation of the semiconductor memory device according to the first embodiment;

FIG. 11 is a schematic view showing the “0” write operation of the semiconductor memory device according to the first embodiment;

FIG. 12 is a schematic view showing a controller according to the first embodiment;

FIG. 13 is a timing chart showing a “1” write operation of the controller according to the first embodiment;

FIG. 14 is a timing chart showing a “0” write operation of the controller according to the first embodiment;

FIG. 15 is a schematic view showing each constituent element according to the second embodiment;

FIG. 16 is a schematic view showing a “1” write operation of a semiconductor memory device according to the second embodiment; and

FIG. 17 is a schematic view showing a “0” write operation of the semiconductor memory device according to the second embodiment.

### DETAILED DESCRIPTION

In a write operation of an MRAM, the direction of a write current flowing through a memory cell in “1” write (AP (Anti-Parallel) write) is opposite to that in “0” write (P (Parallel) write). To supply the bidirectional write currents as described above, a write driver is formed on each of the two sides of a memory cell, i.e., on one side (the bit line side) and the other side (the source line side) of the memory cell. More specifically, one write driver is connected to one global bit line, and one write driver is connected to one global source line.

In “1” write, a write current flows from the power supply potential terminal of the write driver on the bit line side to the ground potential terminal of the write driver on the source line side. That is, a memory cell is set in an AP state by supplying the write current to the memory cell in a direction from the bit line side to the source line side of the memory cell. On the other hand, in “0” write, a write current flows from the power supply potential terminal of the write driver on the source line side to the ground potential terminal of the write driver on the bit line side. That is, a memory cell is set in a P state by supplying the write current to the memory cell in a direction (opposite to the direction in “1” write) from the source line side to the bit line side.

Since the write drivers are arranged on the two sides of a memory cell as described above, the number of write drivers increases, so the circuit area increases.

By contrast, this embodiment solves the above-mentioned problem by reducing write drivers by using a portion of a sense amplifier as a current path in write.

In general, according to one embodiment, a semiconductor memory device includes a memory cell including a variable resistance element, a sense amplifier connected to one side of the memory cell, and a write driver connected to the other side of the memory cell. A write current flows between the sense amplifier and the write driver in a write operation.

This embodiment will be explained below with reference to the accompanying drawings. In these drawings, the same reference numerals denote the same parts. Also, a repetitive explanation will be made as needed.

### First Embodiment

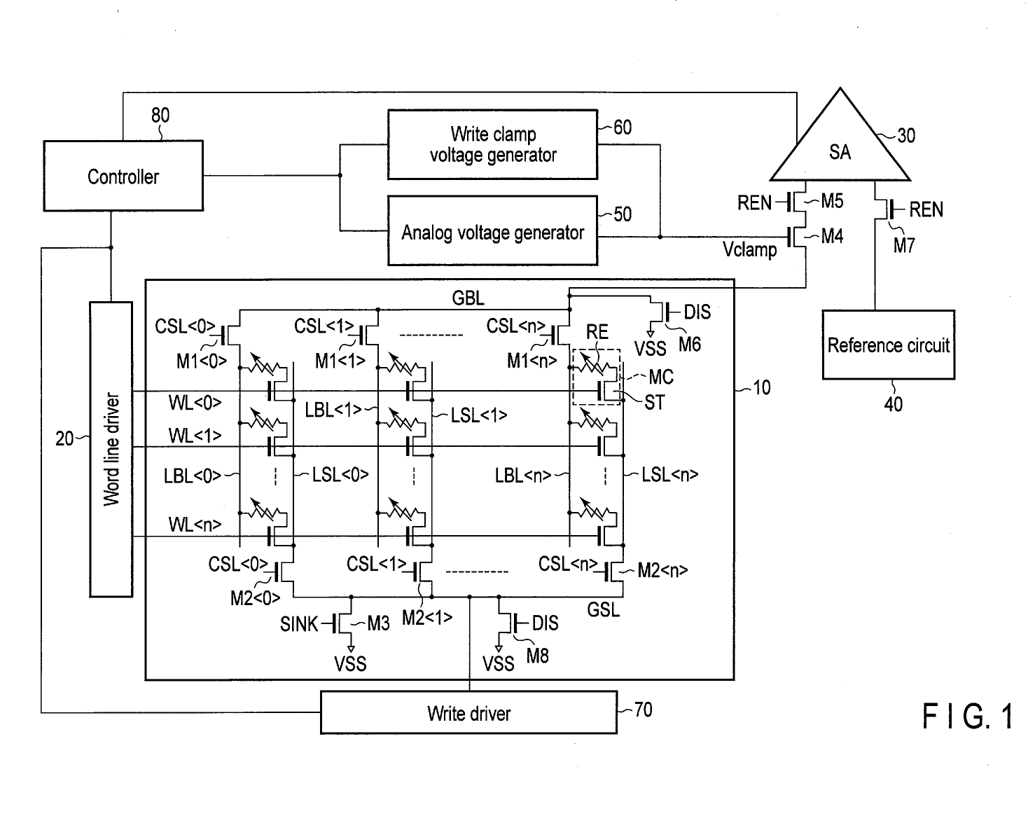

A semiconductor memory device according to the first embodiment will be explained below with reference to FIGS. 1, 2A, 2B, 2C, 3, 4, 5, 6, 7, 8, 9, 10, 11, 12, 13, and 14. In the first embodiment, a write current which uses a portion of a sense amplifier 30 and a portion of a write driver 70 as current paths is generated, and a write operation to a memory cell MC is performed. This makes it possible to reduce a write driver on the side of the sense amplifier 30 of the memory cell MC, and reduce the circuit area and chip size. The first embodiment will be explained in detail below.

### Arrangement and Operation in First Embodiment

The arrangement and operation of the semiconductor memory device according to the first embodiment will be explained with reference to FIGS. 1, 2A, 2B, 2C, 3, 4, 5, 6, 7, 8, 9, 10, 11, 12, 13, and 14. This embodiment will be explained by taking an MRAM which stores data by using a magnetoresistive element (MTJ element) as an example, but the present invention is not limited to this. The first embodiment is applicable to all memories which store data by changing the resistance of a variable resistance element by bidirectionally supplying write currents to a memory cell.

### (Arrangement)

The arrangement of the semiconductor memory device according to the first embodiment will be explained below.

FIG. 1 is a schematic view showing the arrangement of the semiconductor memory device according to the first embodiment.

As shown in FIG. 1, the semiconductor memory device includes a memory cell array 10, write line driver 20, sense amplifier 30, reference circuit 40, analog voltage generator 50, write clamp voltage generator 60, write driver 70, and controller 80.

The memory cell array 10 includes a plurality of memory cells MC arranged in a matrix at positions where local bit lines LBL<0> to LBL<n> and local source lines LSL<0> to LSL<n> intersect word lines WL<0> to WL<n>. Note that n indicates 0, 1, 2, . . . n. Note also that in the following explanation, these lines will be referred to as local bit lines LBL, local source lines LSL, and word lines WL when it is unnecessary to distinguish between them.

The memory cell MC includes a variable resistance element RE and selection transistor ST. The variable resistance element RE has one terminal electrically connected to the local bit line LBL, and the other terminal electrically connected to one end of the current path of the selection transistor ST. The other end of the current path of the selection transistor ST is electrically connected to the local source line LSL. The gate of the selection transistor ST is electrically connected to the word line WL.

The variable resistance element RE is an element which changes the resistance value when a current (or voltage) is applied. The variable resistance element RE includes, e.g., an MTJ element, phase change element, and ferroelectric element. The memory cell MC is selected when the selection transistor ST is turned on by the word line WL. Note that a case in which the variable resistance element RE is an MTJ element will be explained below.

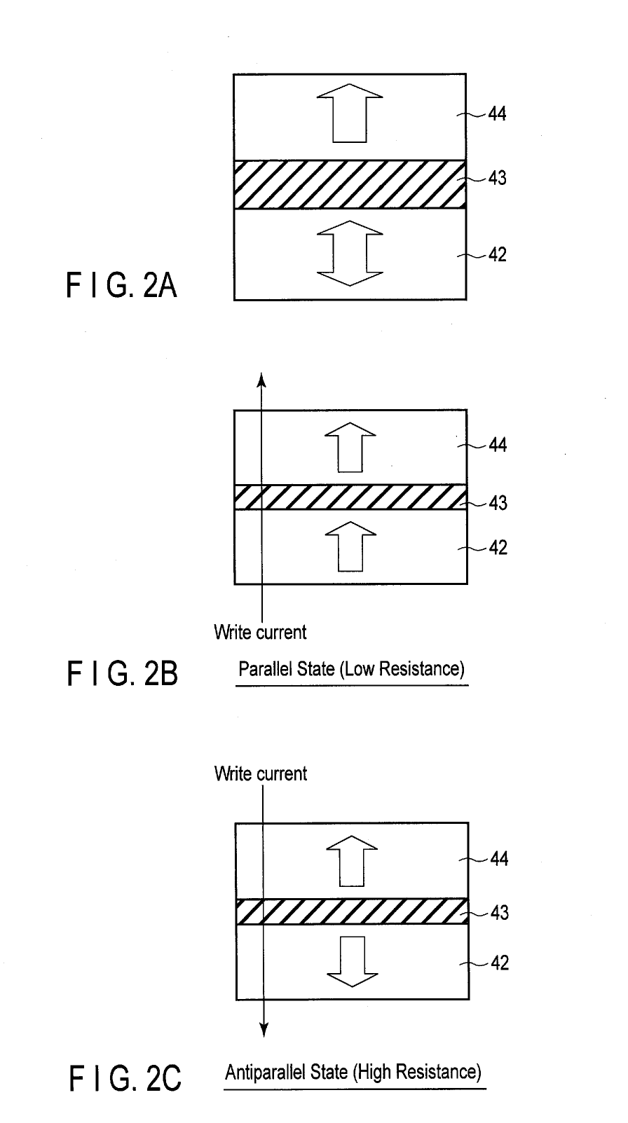

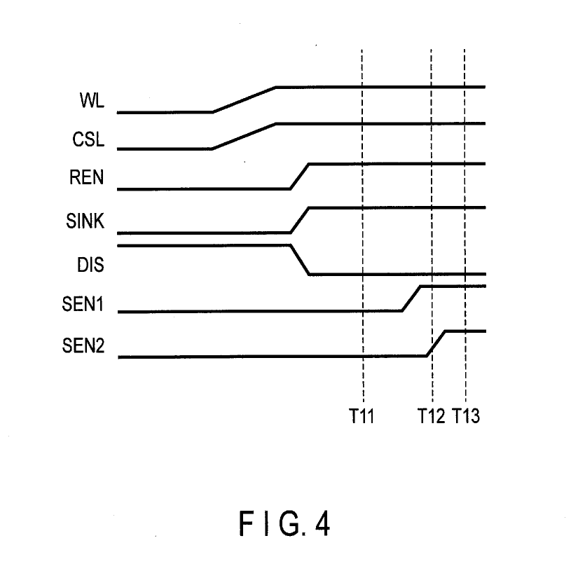

FIG. 2A is a sectional view showing an outline of the arrangement of the variable resistance element (magnetoresistive element) RE. FIG. 4A mainly shows a memory layer 42, tunnel barrier layer 43, and reference layer 44 as the variable resistance element RE.

As shown in FIG. 2A, the variable resistance element RE has a stack including the memory layer 42 as a ferromagnetic layer, the reference layer 44 as a ferromagnetic layer, and the tunnel barrier layer 43 as a nonmagnetic layer formed between them.

The memory layer 42 is a ferromagnetic layer in which the magnetization direction is variable, and has perpendicular magnetic anisotropy which is perpendicular to or almost perpendicular to the film surfaces (upper surface/lower surface). “The magnetization direction is variable” herein mentioned indicates that the magnetization direction changes with respect to a predetermined write current. Also, “almost perpendicular” means that the direction of residual magnetization falls within the range of 45°<θ≦90° with respect to the film surfaces.

The tunnel barrier layer 43 is formed on the memory layer 42. The tunnel barrier layer 43 is a nonmagnetic layer, and made of, e.g., MgO.

The reference layer 44 is formed on the tunnel barrier layer 43. The reference layer 44 is a ferromagnetic layer in which the magnetization direction is invariable, and has perpendicular magnetic anisotropy which is perpendicular to or almost perpendicular to the film surfaces. “The magnetization direction is invariable” herein mentioned indicates that the magnetization direction is invariable with respect to the predetermined write current. That is, the reference layer 44 has a switching energy barrier larger than that of the memory layer 42 in the magnetization direction.

FIG. 2B is a sectional view for explaining a write operation of the magnetoresistive element in a parallel state (P state). FIG. 2C is a sectional view for explaining a write operation of the magnetoresistive element in an antiparallel state (AP state).

The variable resistance element RE is, e.g., a spin transfer torque magnetoresistive element. Therefore, when writing data to the variable resistance element RE or reading data from the variable resistance element RE, currents are bidirectionally supplied to the variable resistance element RE in a direction perpendicular to the film surfaces.

More specifically, data is written to the variable resistance element RE as follows.

As shown in FIG. 2B, when a current flows from the memory layer 42 to the reference layer 44, i.e., when electrons moving from the reference layer 44 to the memory layer 42 are supplied, electrons spin-polarized in the same direction as the magnetization direction in the reference layer 44 are injected into the memory layer 42. In this case, the magnetization direction in the memory layer 42 is matched with that in the reference layer 44. Consequently, the magnetization directions in the reference layer 44 and memory layer 42 are arranged parallel. In this parallel state, the resistance value of the variable resistance element RE is smallest. This state is defined as, e.g., data “0”.

On the other hand, as shown in FIG. 2C, when a current flows from the reference layer 44 to the storage layer 42, i.e., when electrons moving from the memory layer 42 to the reference layer 44 are supplied, electrons reflected by the reference layer 44 and thereby spin-polarized in a direction opposite to the magnetization direction in the reference layer 44 are injected into the memory layer 42. In this case, the magnetization direction in the memory layer 42 is matched with the direction opposite to the magnetization direction in the reference layer 44. Consequently, the magnetization directions in the reference layer 44 and memory layer 42 are arranged antiparallel. In this antiparallel state, the resistance value of the variable resistance element RE is largest. This state is defined as, e.g., data “1”.

Also, data is read from the variable resistance element RE as follows.

A read current is supplied to the variable resistance element RE. This read current is set at a value (a value smaller than the write current) with which the magnetization direction in the memory layer 42 does not reverse. The above-mentioned data “0” or “1” can be read by detecting the change in resistance value of the variable resistance element RE in this state.

Again, as shown in FIG. 1, one end of each of the local source lines LSL<0> to LSL<n> is electrically connected to a global source line GSL via a corresponding one of column selection transistors M2<0> to M2<n> (LYSW (Local Column Switch)). Column selection signals CSL<0> to CSL<n> are respectively supplied to the gates of the column selection transistors M2<0> to M2<n>.

The global source line GSL is electrically connected to a ground potential terminal VSS via the current path of an NMOS transistor (sink transistor) M3. A sink signal SINK is supplied to the gate of the NMOS transistor M3. The global source line GSL is also electrically connected to the ground potential terminal VSS via the current path of an NMOS transistor (discharge transistor) M8. A discharge signal DIS is supplied to the gate of the NMOS transistor M8. Furthermore, the global source line GSL is electrically connected to the write driver 70.

One end of each of the local bit lines LBL<0> to LBL<n> is electrically connected to a global bit line GBL via a corresponding one of column selection transistors M1<0> to M1<n>. Column selection signals CSL<0> to CSL<n> are respectively supplied to the gates of the column selection transistors M1<0> to M1<n>.

The global bit line GBL is electrically connected to the first input terminal of the sense amplifier 30 via the current path of an NMOS transistor (clamp transistor) M4 and the current path of an NMOS transistor (read enable transistor) M5. The write clamp voltage generator 60 and analog voltage generator 50 supply a clamp signal Vclamp to the gate of the clamp transistor M4. A read enable signal REN is supplied to the gate of the read enable transistor M5. The global bit line GBL is also electrically connected to the ground potential terminal VSS via the current path of an NMOS transistor (discharge transistor) M6. The discharge signal DIS is supplied to the gate of the NMOS transistor M6.

The reference circuit 40 includes a reference cell in which data “1” is stored, and a reference cell in which data “0” is stored. By using these reference cells, the reference circuit 40 generates a reference current intermediate between data “1” and data “0”. The reference circuit 40 is electrically connected to the second input terminal of the sense amplifier 30 via an NMOS transistor (read enable transistor) M7. The read enable signal REN is supplied to the gate of the NMOS transistor M7.

Note that the reference circuit 40 may also have a fixed resistance instead of the reference cells, and generate a reference current by using the fixed resistance.

The sense amplifier 30 is electrically connected to one side (the global bit line GBL side) of the memory cell array 10. More specifically, the sense amplifier 30 has a first input terminal electrically connected to the global bit line GBL (one side) via the current path of the read enable transistor M5 and the current path of the clamp transistor M4, and a second input terminal electrically connected to the reference circuit 40 via the current path of the NMOS transistor M7. The sense amplifier 30 is a current detection type sense amplifier.

The write driver 70 is electrically connected to the global source line GSL (the other side) of the memory cell array 10. A write current flows out from or flows into the write driver 70.

The word line driver 20 is electrically connected to the word lines WL, and selectively drive the word lines WL.

The analog voltage generator 50 supplies the clamp signal Vclamp as an analog voltage (a voltage at an “M (Middle)” level (e.g., 0.1 to 0.6 V)) to the gate of the clamp transistor M4.

The write clamp voltage generator 60 supplies the clamp signal Vclamp as an “L (Low)” level (e.g., 0 V) or “H (High)” level (e.g., 1.2 V) to the gate of the clamp transistor M4.

The controller 80 controls the operations of the word line driver 20, sense amplifier 30, analog voltage generator 50, write clamp voltage generator 60, and sense amplifier 70.

Details of the sense amplifier 30, analog voltage generator 50, write clamp voltage generator 60, write driver 70, and controller 80 will be described later.

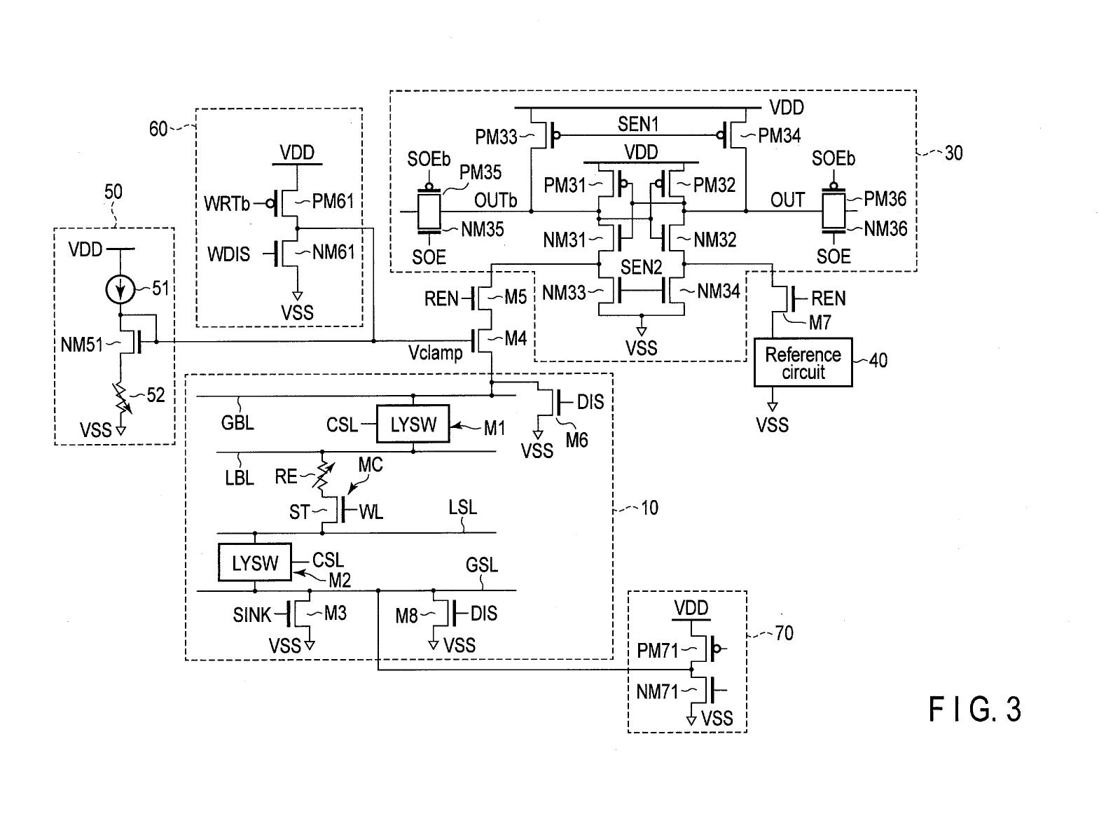

FIG. 3 is a schematic view showing each constituent element according to the first embodiment. Note that FIG. 3 omits the word line driver 20 and controller 80. Note also that only one memory cell MC is shown in the memory cell array 10.

As shown in FIG. 3, the sense amplifier 30 includes a first inverter, a second inverter, NMOS transistors (sense enable transistors) NM33 and NM34, PMOS transistors (sense enable transistors) PM33 and PM34, first path transistors, and second pass transistors.

The first inverter includes a PMOS transistor PM31 and NMOS transistor NM31. The first inverter has a first input terminal, a first output terminal, and first and second voltage terminals. The second inverter includes a PMOS transistor PM32 and NMOS transistor NM32. The second inverter has a second input terminal, a second output terminal, and third and fourth voltage terminals.

The first voltage terminal (one terminal of the PMOS transistor PM31) and the third voltage terminal (one terminal of the PMOS transistor PM32) are electrically connected to a power supply potential terminal VDD. The second input terminal (the gates of the PMOS transistor PM32 and NMOS transistor NM32) is electrically connected to the first output terminal (the other terminal of the PMOS transistor PM31 and one terminal of the NMOS transistor NM31). The second output terminal (the other terminal of the PMOS transistor PM32 and one terminal of the NMOS transistor NM32) is electrically connected to the first input terminal (the gates of the PMOS transistor PM31 and NMOS transistor NM31).

The first pass transistors include an NMOS transistor NM35 and PMOS transistor PM35. The second pass transistors include an NMOS transistor NM36 and PMOS transistor PM36.

One end of the current path of the PMOS transistor PM33 is electrically connected to the first output terminal of the first inverter, and the other end of the current path of the PMOS transistor PM33 is electrically connected to the power supply potential terminal VDD. One end of the current path of the PMOS transistor PM34 is electrically connected to the second output terminal of the second inverter, and the other end of the current path of the PMOS transistor PM34 is electrically connected to the power supply potential terminal VDD. A sense enable signal SEN1 is supplied to the gates of the PMOS transistors PM33 and PM34.

The first pass transistors (the NMOS transistor NM35 and PMOS transistor PM35) are electrically connected to the first output terminal of the first inverter. Output enable signals SOE and SOEb are respectively supplied to the gates of the NMOS transistor NM35 and PMOS transistor PM35. The second pass transistors (the NMOS transistor NM36 and PMOS transistor PM36) are electrically connected to the second output terminal of the second inverter. The output enable signals SOE and SOEb are respectively supplied to the gates of the NMOS transistor NM36 and PMOS transistor PM36.

One end of the current path of the NMOS transistor NM33 is electrically connected to the second voltage terminal (the other end of the current path of the NMOS transistor NM31) of the first inverter, and the other end of the current path of the NMOS transistor NM33 is electrically connected to the ground potential terminal VSS. One end of the current path of the NMOS transistor NM34 is electrically connected to the fourth voltage terminal (the other end of the current path of the NMOS transistor NM32) of the second inverter, and the other end of the current path of the NMOS transistor NM34 is electrically connected to the ground potential terminal VSS. A sense enable signal SEN2 is supplied to the gates of the NMOS transistors NM33 and NM34.

The second voltage terminal (the other end of the current path of the NMOS transistor NM31, i.e., the first input terminal of the sense amplifier 30) of the first inverter is electrically connected to one end of the current path of the read enable transistor M5. The other end of the current path of the read enable transistor M5 is electrically connected to one end of the current path of the clamp transistor M4. The other end of the current path of the clamp transistor M4 is electrically connected to the global bit line GBL.

The fourth voltage terminal (the other end of the current path of the NMOS transistor NM32, i.e., the second input terminal of the sense amplifier 30) of the second inverter is electrically connected to one end of the current path of the read enable transistor M7. The other end of the current path of the read enable transistor M7 is electrically connected to the reference circuit 40.

The analog voltage generator 50 includes a constant current source 51, NMOS transistor NM51, and variable resistor 52. The drain and gate of the NMOS transistor NM51 are electrically connected by a diode connection. The constant current source 51 for supplying a constant current is electrically connected to the drain of the NMOS transistor NM51. One terminal of the variable resistor 52 is electrically connected to the source of the NMOS transistor NM51, and the ground potential terminal VSS is electrically connected to the other terminal of the variable resistor 52. The analog voltage generator 50 supplies an ‘M’-level clamp signal Vclamp from the gate of the NMOS transistor NM51 to the gate of the NMOS transistor M4.

The write clamp voltage generator 60 includes an NMOS transistor NM61 and PMOS transistor PM61. One end of the current path of the PMOS transistor PM61 is electrically connected to the power supply potential terminal VDD, and the other end is electrically connected to one end of the current path of the NMOS transistor NM61. The other end of the current path of the NMOS transistor NM61 is electrically connected to the ground potential terminal. A signal WRTb is supplied to the gate of the PMOS transistor PM61, and a signal WDIS is supplied to the gate of the NMOS transistor NM61. The write clamp voltage generator 60 supplies an “L”-level or “H”-level clamp signal Vclamp from the connection terminal of the PMOS transistor PM61 and NMOS transistor NM61 (the other terminal of the PMOS transistor PM61 and one terminal of the NMOS transistor NM61) to the gate of the NMOS transistor M4. Although not shown, the write clamp voltage generator 60 is connected in common to the gates of a plurality clamp transistors.

The write driver 70 includes an NMOS transistor NM71 and PMOS transistor PM71. One end of the current path of the PMOS transistor PM71 is electrically connected to the power supply potential terminal VDD, and the other end is electrically connected to one end of the current path of the NMOS transistor NM71. The other end of the current path of the NMOS transistor NM71 is electrically connected to the ground potential terminal. An “H”-level or “L”-level signal is supplied to the gates of the PMOS transistor PM71 and NMOS transistor NM71. The connection terminals of the PMOS transistor PM71 and NMOS transistor NM71 (the other terminal of the PMOS transistor PM71 and one terminal of the NMOS transistor NM71) are electrically connected to the global bit line GBL.

### (Read Operation)

A read operation of the semiconductor memory device according to the first embodiment will be explained below.

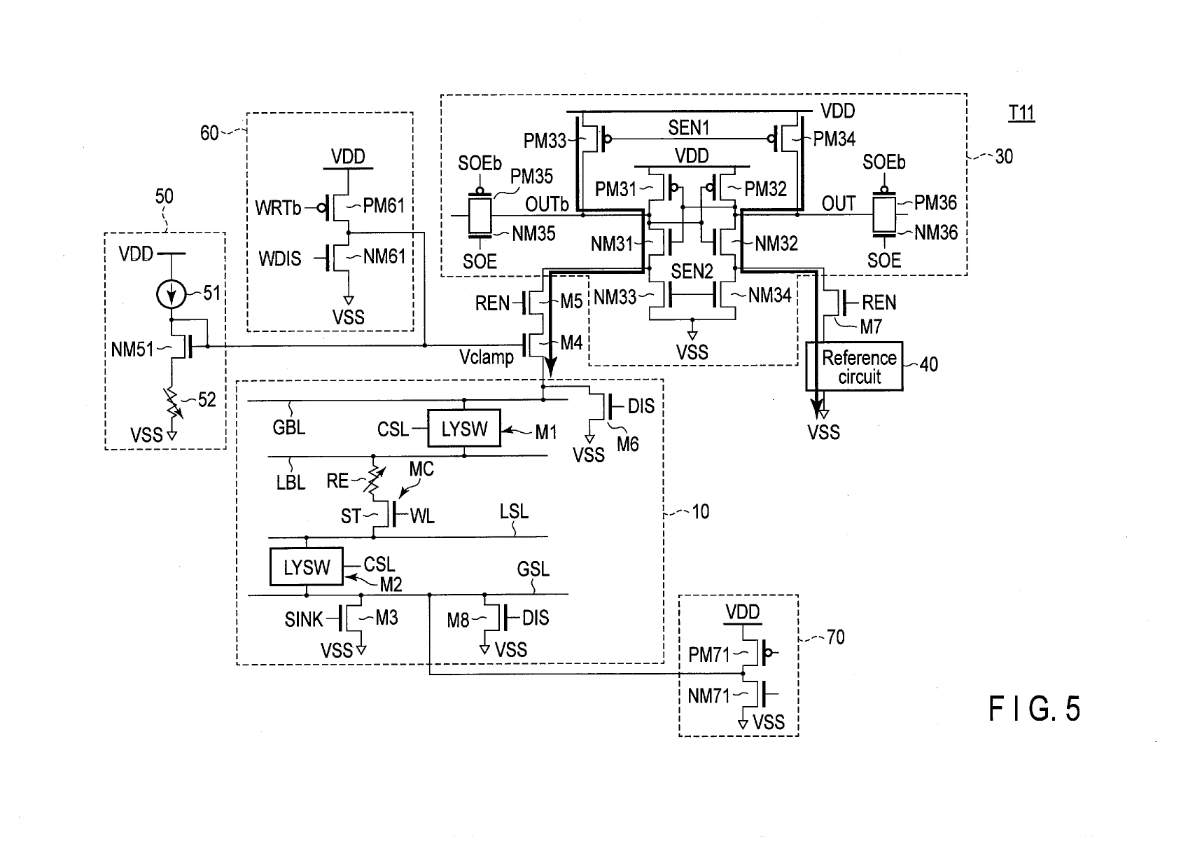

FIG. 4 is a timing chart showing the read operation of the semiconductor memory device according to the first embodiment. FIGS. 5, 6, and 7 are schematic views showing the read operation at times T11 to T13 of the semiconductor memory device according to the first embodiment.

First, as shown in FIG. 4, in a standby state before the read operation is started (before time T11), the sense enable signal SEN1 is at “L” level, and the sense enable transistors PM33 and PM34 are ON. The discharge signal DIS is at “H” level, and the discharge transistors M6 and M8 are ON.

Also, the word line WL, column selection signal CSL<n>, sink signal SINK, sense enable signal SEN2, signal SOE, and read enable signal REN are at “L” level, and the signal SOEb is at “H” level. Accordingly, MOS transistors connected to these signals are OFF. In addition, the analog voltage generator 50 sets the clamp signal Vclamp at “M” level as an analog signal, and the clamp transistor M4 is turned on in accordance with “M” level.

Note that the signal WRTb is at “H” level, and the signal WDIS is at “L” level, so the PMOS transistor PM61 and NMOS transistor NM61 are OFF. Therefore, the write clamp voltage generator 60 does not operate.

Then, as shown in FIGS. 4 and 5, in the initial state (time T11) of the read operation, the sense enable signal SEN1 is at “L” level, and nodes OUT and OUTb are precharged to the power supply voltage VDD.

Also, the column selection signal CSL<n> changes to “H” level, and the local bit line LBL<n> and local source line LSL<n> are selected. In addition, the memory cell MC as a read target is selected by driving the word line WL<n>. Furthermore, the discharge signal DIS changes to “L” level, and the discharge transistors M6 and M8 are turned off. The sink signal SINK changes to “H” level, and the sink transistor M3 is turned on. The timing at which the sink transistor M3 is turned on is before a read current flows to the memory cell MC. Also, the read enable signal REN changes to “H” level, and the read enable transistor M5 is turned on.

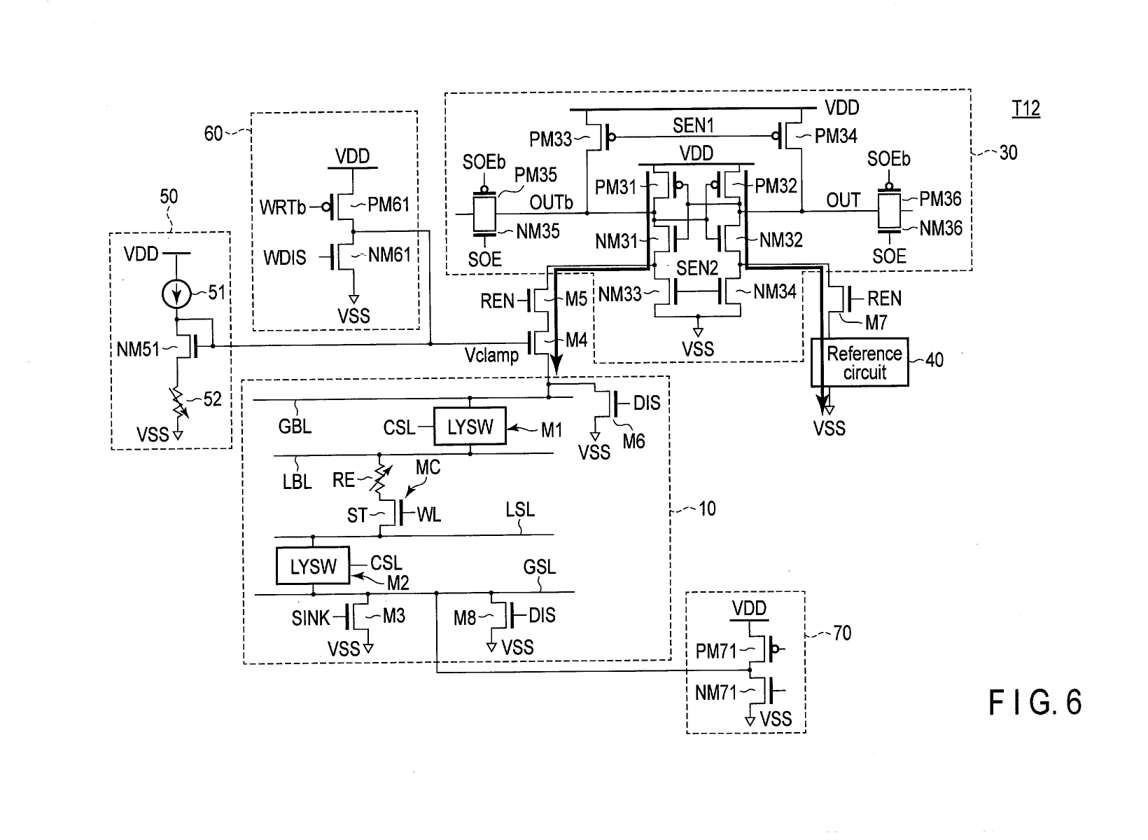

Subsequently, at time T12 as shown in FIGS. 4 and 6, the sense enable signal SEN1 changes to “H” level, and the sense enable transistors PM33 and PM34 are turned off. Therefore, the precharge of the nodes OUT and OUTb is stopped. As a consequence, the read current is supplied from only the power supply potential terminal VDD connected to one terminal of each of the PMOS transistors PM31 and PM32. In this state, the read current changes in accordance with data (“0” or “1”) stored in the selected memory cell MC. That is, the read current changes in accordance with whether the selected memory cell MC is in the low-resistance state or high-resistance state.

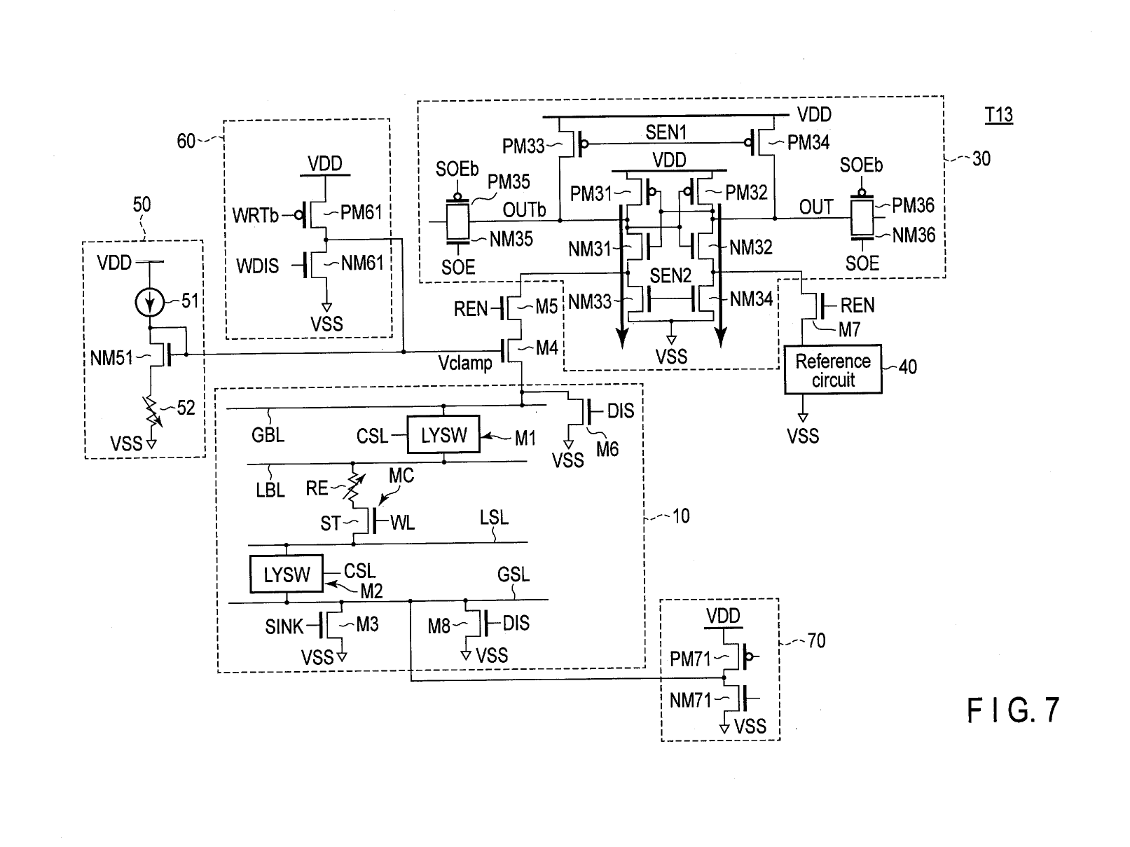

After that, at time T13 as shown in FIGS. 4 and 7, the sense enable signal SEN2 changes to “H” level, and the sense enable transistors NM33 and NM34 are turned on. Therefore, the read current flowing to the first input terminal of the sense amplifier 30 and the reference current flowing to the second input terminal are compared. Then, a latch circuit including the PMOS transistors PM31 and PM32 and NMOS transistors NM31 and NM32 holds “H” or “L” level in accordance with the comparison result.

Finally, the output enable signal SOE changes to “H” level, and the output enable signal SOEb changes to “L” level, so the NMOS transistors NM35 and NM36 and PMOS transistors PM35 and PM36 are turned on. Consequently, the “H” or “L” level held in the latch circuit is output as output signals from the nodes OUT and OUTb.

### (Write Operation)

A write operation of the semiconductor memory device according to the first embodiment will be explained below.

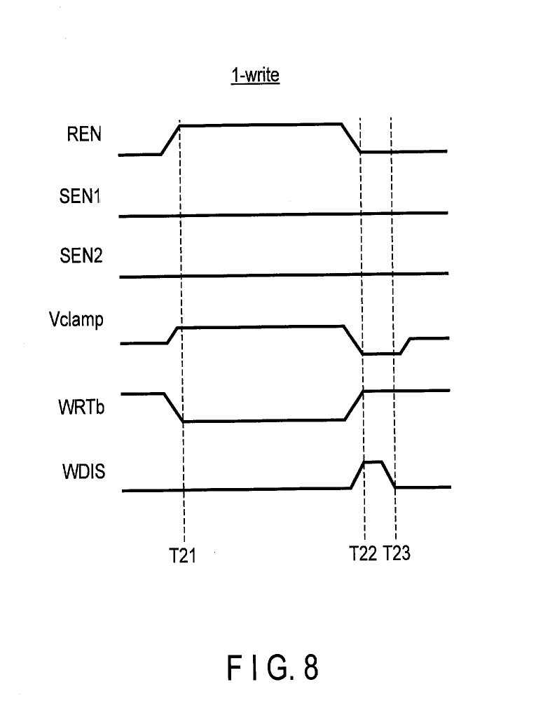

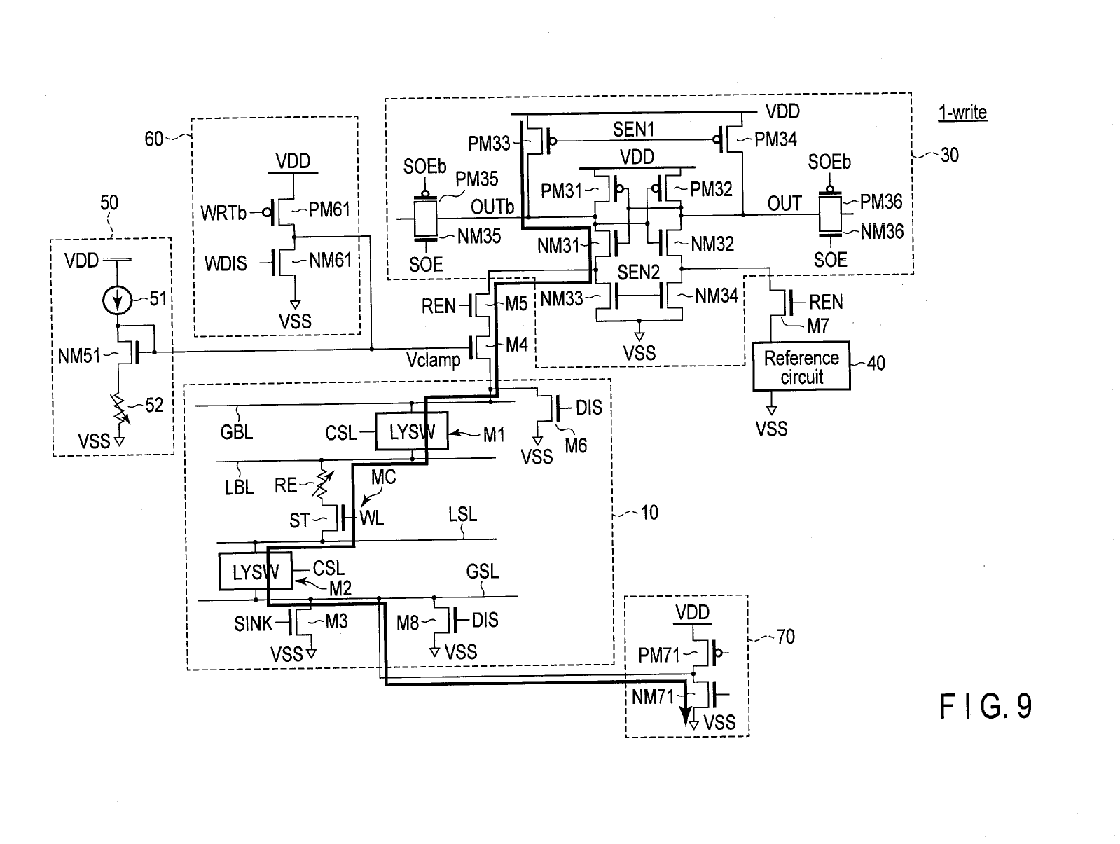

FIG. 8 is a timing chart showing a “1” write operation of the semiconductor memory device according to the first embodiment. FIG. 9 is a schematic view showing the “1” write operation of the semiconductor memory device according to the first embodiment.

First, as shown in FIG. 8, in a standby state before the “1” write operation is started (before time T21), the read enable signal REN and sense enable signals SEN1 and SEN2 are at “L” level. Accordingly, the read enable transistor M5 and sense enable transistors NM33 and NM34 are OFF, and the sense enable transistors PM33 and PM34 are ON.

Also, the signal WRTb is at “H” level, and the signal WDIS is at “L” level, so the PMOS transistor PM61 and NMOS transistor NM61 are OFF. The analog signal generator 50 sets the clamp signal Vclamp at “M” level. In addition, an “H”-level signal is supplied to the gate of the PMOS transistor PM71, and an “L”-level signal is supplied to the gate of the NMOS transistor NM71, so the PMOS transistor PM71 and NMOS transistor NM71 are turned off.

Furthermore, the signal SOE is at “L” level, and the signal SOEb is at “H” level, so the PMOS transistors PM35 and PM36 and NMOS transistors NM35 and NM36 are OFF.

In this state, the write driver 70 and sense amplifier 30 do not operate and are deactivated.

Then, at time T21, the read enable signal REN changes to “H” level, and the read enable transistor M5 is turned on. Also, the signal WRTb changes to “L” level, and the PMOS transistor PM61 is turned on. Accordingly, the clamp signal Vclamp changes to “H” level by using the PMOS transistor PM61 as a trigger. In addition, an “H”-level signal is supplied to the gate of the NMOS transistor NM71, so the NMOS transistor NM71 is turned on.

Also, the discharge signal DIS and sink signal SINK are at “L” level, and the discharge transistors M6 and M8 and sink transistor M3 are OFF.

By holding this state for a predetermined period, as shown in FIG. 9, a “1” write current flows in a direction from the sense amplifier 30 to the write driver 70. More specifically, the “1” write current flows from the power supply potential terminal VDD of the sense amplifier 30 to the ground potential terminal VSS of the write driver 70 via the PMOS transistor PM33, NMOS transistor NM31, read enable transistor M5, clamp transistor M4, memory cell MC, and NMOS transistor NM71 in this order. As a consequence, data “1” is written to the memory cell MC.

Subsequently, at time T22 after the write operation is terminated, the read enable signal REN changes to “L” level, and the read enable transistor M5 is turned off. Also, the signals WRTb and WDIS change to “H” level, so the PMOS transistor PM61 is turned off, and the NMOS transistor NM61 is turned on. Accordingly, the signal Vclamp changes to “L” level by using the NMOS transistor NM61 as a trigger.

After that, at time T23, the signal WDIS changes to “L” level, and the NMOS transistor NM61 is turned off. Consequently, the analog voltage generator 50 sets the signal Vclamp at “M” level, thereby setting the semiconductor memory device in the standby state.

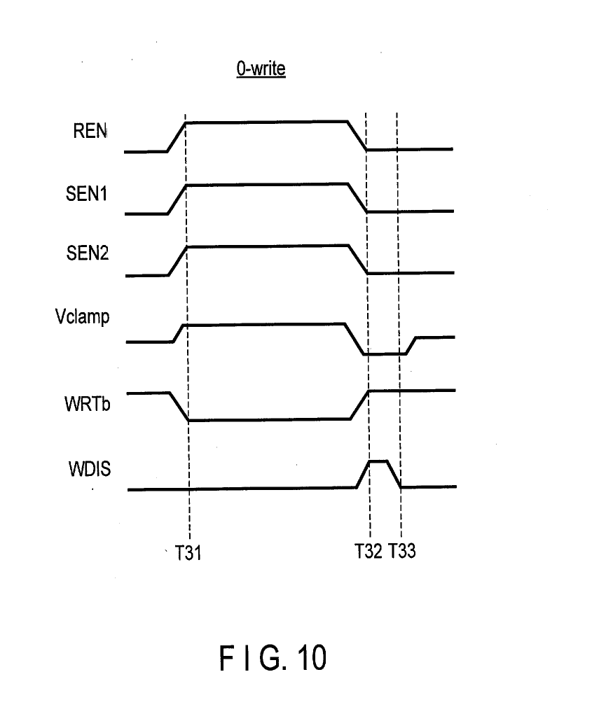

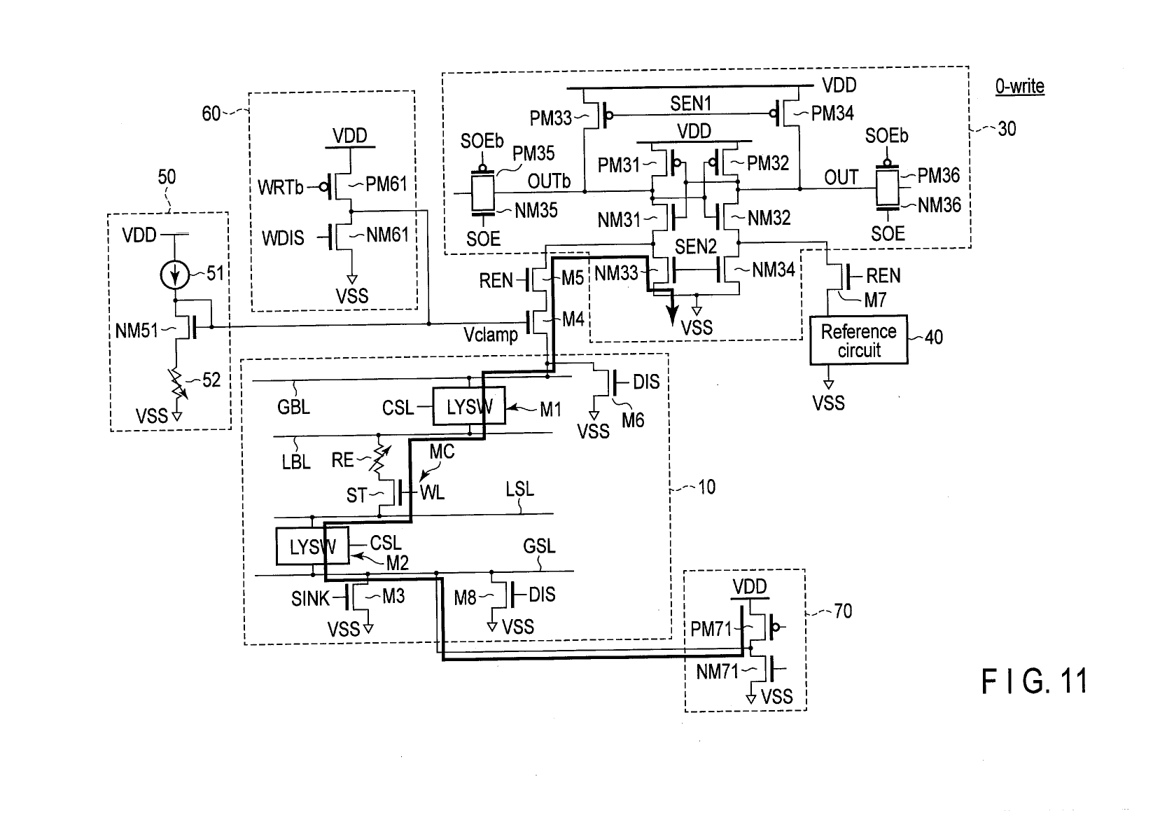

FIG. 10 is a timing chart showing a “0” write operation of the semiconductor memory device according to the first embodiment. FIG. 11 is a schematic view showing the “0” write operation of the semiconductor memory device according to the first embodiment.

First, as shown in FIG. 10, in a standby state before the “0” write operation is started (before time T31), the read enable signal REN and sense enable signals SEN1 and SEN2 are at “L” level. Accordingly, the read enable transistor M5 and sense enable transistors NM33 and NM34 are OFF, and the sense enable transistors PM33 and PM34 are ON.

Also, the signal WRTb is at “H” level, and the signal WDIS is at “L” level, so the PMOS transistor PM61 and NMOS transistor NM61 are OFF. The analog signal generator 50 sets the clamp signal Vclamp at “M” level. In addition, an “H”-level signal is supplied to the gate of the PMOS transistor PM71, and an “L”-level signal is supplied to the gate of the NMOS transistor NM71, so the PMOS transistor PM71 and NMOS transistor NM71 are turned off.

Furthermore, the signal SOE is at “L” level, and the signal SOEb is at “H” level, so the PMOS transistors PM35 and PM36 and NMOS transistors NM35 and NM36 are OFF.

In this state, the write driver 70 and sense amplifier 30 do not operate and are deactivated.

Then, at time T31, the read enable signal REN changes to “H” level, and the read enable transistor M5 is turned on. Also, the signal WRTb changes to “L” level, and the PMOS transistor PM61 is turned on. Accordingly, the clamp signal Vclamp changes to “H” level by using the PMOS transistor PM61 as a trigger. In addition, an “L”-level signal is supplied to the gate of the PMOS transistor PM71, so the PMOS transistor PM71 is turned on.

Also, the sense enable signals SEN1 and SEN2 change to “H” level, so the sense enable transistors NM33 and NM34 are turned on, and the sense enable transistors PM33 and PM34 are turned off.

In addition, the discharge signal DIS and sink signal SINK are at “L” level, and the discharge transistors M6 and M8 and sink transistor M3 are OFF.

By holding this state for a predetermined period, as shown in FIG. 11, a “0” write current flows in a direction from the write driver 70 to the sense amplifier 30. More specifically, the “0” write current flows from the power supply potential terminal VDD of the write driver 70 to the ground potential terminal VSS of the sense amplifier 30 via the PMOS transistor PM71, memory cell MC, clamp transistor M4, read enable transistor M5, and NMOS transistor NM33 in this order. As a consequence, data “0” is written to the memory cell MC.

Subsequently, at time T32 after the write operation, the read enable signal REN changes to “L” level, and the read enable transistor M5 is turned off. Also, the signals SEN1 and SEN2 change to “L” level, so the sense enable transistors NM33 and NM34 are turned off, and the sense enable transistors PM33 and PM34 are turned on. In addition, the signals WRTb and WDIS change to “H” level, so the PMOS transistor PM61 is turned off, and the NMOS transistor NM61 is turned on. Accordingly, the signal Vclamp changes to “L” level by using the NMOS transistor NM61 as a trigger.

After that, at time T33, the signal WDIS changes to “L” level, and the NMOS transistor NM61 is turned off. Consequently, the analog voltage generator 50 sets the signal Vclamp at “M” level, thereby setting the semiconductor memory device in the standby state.

### (Arrangement and Operation of Controller)

The arrangement and operation of the controller which implements the above-mentioned write operations will be explained below.

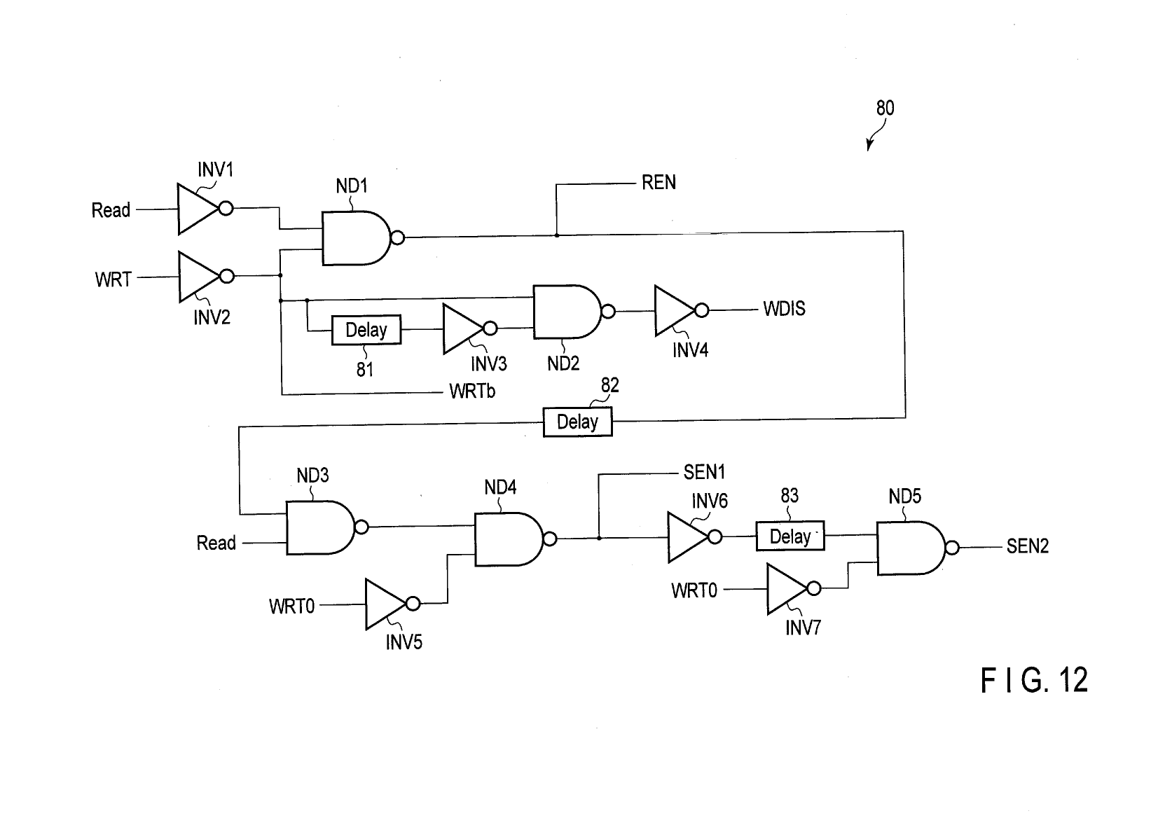

FIG. 12 is a schematic view showing the controller according to the first embodiment.

As shown in FIG. 12, the controller 80 includes inverters INV1 to INV7, NAND gates ND1 to ND5, and delay circuits 81 to 83.

The inverter INV1 inverts an externally input read signal Read (a read command) and outputs the inverted signal. The inverter INV2 inverts an externally input write signal WRT (a write command) and outputs the inverted signal.

The delay circuit 81 delays the output signal from the inverter INV2 and outputs the delayed signal. The inverter INV3 inverts the output signal from the delay circuit 81 and outputs the inverted signal. The NAND gate ND2 performs a NAND operation on the output signals from the inverters INV2 and INV3 and outputs the operation result. The inverter INV4 inverts the output signal from the NAND gate ND2 and outputs the inverted signal.

The NAND gate ND1 performs a NAND operation on the output signals from the inverters INV1 and INV2 and outputs the operation result. The delay circuit 82 delays the output signal from the NAND gate ND1 and outputs the delayed signal.

The NAND gate ND3 performs a NAND operation on the output signal from the delay circuit 82 and the externally input read signal Read and outputs the operation result. The inverter INV5 inverts an externally input “0” write signal WRT0 (a “0” write command) and outputs the inverted signal. The NAND gate ND4 performs a NAND operation on the output signals from the NAND gate ND3 and inverter INV5 and outputs the operation result.

The inverter INV6 inverts the output signal from the NAND gate ND4 and outputs the inverted signal. The delay circuit 83 delays the output signal from the inverter INV6 and outputs the delayed signal. The inverter INV7 inverts the externally input “0” write signal WRT0 and outputs the inverted signal. The NAND gate ND5 performs a NAND operation on the output signals from the delay circuit 83 and inverter INV7 and outputs the operation result.

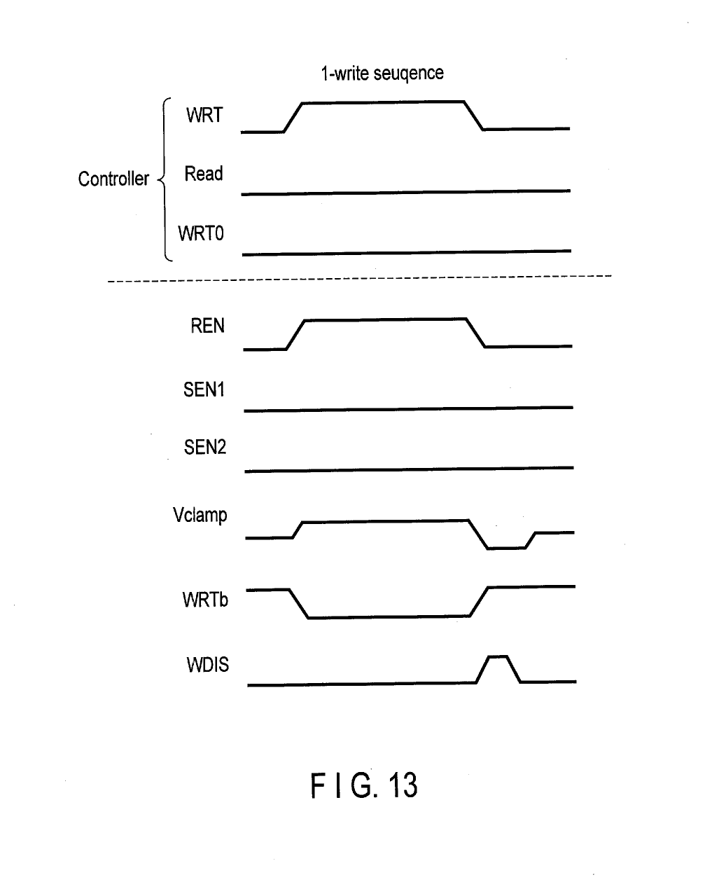

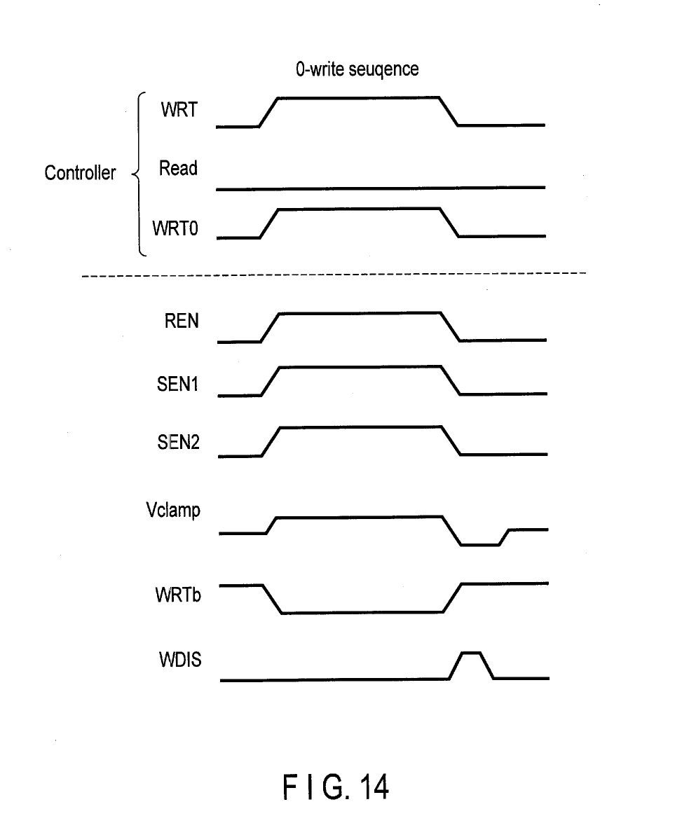

FIG. 13 is a timing chart showing a “1” write operation of the controller according to the first embodiment. FIG. 14 is a timing chart showing a “0” write operation of the controller according to the first embodiment. Note that FIG. 13 also shows the various signals shown in FIG. 8, and FIG. 14 also shows the various signals shown in FIG. 10.

In the “1” write operation as shown in FIG. 13, the write signal WRT changes to “H” level while the read signal Read and “0” write signal WRT0 are at “L” level. Consequently, various signals (WRTb, WDIS, REN, SEN1, and SEN2) for the “1” write operation are generated as follows.

The inverter INV2 inverts the “H”-level write signal WRT and outputs an “L”-level signal. Accordingly, the signal WRTb is output at “L” level.

The inverter INV3 inverts the “L”-level output signal from the inverter INV2, which is delayed by the delay circuit 81, and outputs an “H”-level signal. The NAND gate ND2 performs a NAND operation on the “L”-level output signal from the inverter INV2 and the “H”-level output signal from the inverter INV3, and outputs an “H”-level signal. The inverter INV4 inverts the “H”-level signal from the NAND gate ND2 and outputs an “L”-level signal. Consequently, the signal WDIS is output at “L” level.

The clamp signal Vclamp changes to “H” level because the signal WRTb and WDIS are changed to “L” level.

The inverter INV1 inverts the “L”-level read signal Read and outputs an “H”-level signal. The NAND gate ND1 performs a NAND operation on the “H”-level output signal from the inverter INV1 and the “L”-level output signal from the inverter INV2, and outputs an “H”-level signal. Consequently, the read enable signal REN is output at “H” level.

The NAND gate ND3 performs a NAND operation on the “H”-level output signal from the NAND gate ND1, which is delayed by the delay circuit 82, and the “L”-level read signal Read, and outputs an “H”-level signal. On the other hand, the inverter INV5 inverts the “L”-level “0” write signal WRT0 and outputs an “H”-level signal. The NAND gate ND4 performs a NAND operation on the “H”-level output signal from the NAND gate ND3 and the “H”-level output signal from the inverter INV5, and outputs an “L”-level signal. Accordingly, the sense enable signal SEN1 is output at “L” level.

The inverter INV6 inverts the “L”-level output signal from the NAND gate ND4 and outputs an “H”-level signal. On the other hand, the inverter INV7 inverts the “L”-level “0” write signal WRT0 and outputs an “H”-level signal. The NAND gate ND5 performs a NAND operation on the “H”-level output signal from the inverter INV6, which is delayed by the delay circuit 83, and the “H”-level output signal from the inverter INV7, and outputs an “L”-level signal. As a consequence, the sense enable signal SEN2 is output at “L” level.

Thus, the various signals for the “1” write operation are generated.

Note that when the “1” write operation is terminated, the write signal WRT changes to “L” level. Therefore, the NAND gate ND2 receives the “H”-level output signal from the inverter INV2 and the “H”-level output signal from the inverter INV3, which is delayed by the delay circuit 81. By performing a NAND operation on these signals, the NAND gate ND2 outputs an “L”-level signal. As a result, the “H”-level signal WDIS inverted by the inverter INV4 is temporarily output. In addition, the “H”-level signal WRTb is output. Consequently, the clamp signal Vclamp changes to “L” level.

On the other hand, in the “0” write operation as shown in FIG. 14, the write signal WRT and “0” write signal WRT0 change to “H” level while the read signal Read is at “L” level. Consequently, various signals (WRTb, WDIS, REN, SEN1, and SEN2) for the “0” write operation are generated as follows.

The inverter INV2 inverts the “H”-level write signal WRT and outputs an “L”-level signal. Accordingly, the signals WRTb and WDIS are output at “L” level, and the clamp signal Vclamp changes to “H” level, as in the “1” write operation.

The inverter INV1 inverts the “L”-level read signal Read and outputs an “H”-level signal. Consequently, the read enable signal REN is output at “H” level as in the “1” write operation.

The NAND gate ND3 performs a NAND operation on the “H”-level output signal from the NAND gate ND1, which is delayed by the delay circuit 82, and the “L”-level read signal Read, and outputs an “H”-level signal. On the other hand, the inverter INV5 inverts the “H”-level “0” write signal WRT0 and outputs an “L”-level signal. The NAND gate ND4 performs a NAND operation on the “H”-level output signal from the NAND gate ND3 and the “L”-level output signal from the inverter INV5, and outputs an “H”-level signal. Accordingly, the sense enable signal SEN1 is output at “H” level.

The inverter INV6 inverts the “H”-level output signal from the NAND gate ND4 and outputs an “L”-level signal. On the other hand, the inverter INV7 inverts the “H”-level “0” write signal WRT0 and outputs an “L”-level signal. The NAND gate ND5 performs a NAND operation on the “L”-level output signal from the inverter INV6, which is delayed by the delay circuit 83, and the “L”-level output signal from the inverter INV7, and outputs an “H”-level signal. As a consequence, the sense enable signal SEN2 is output at “H” level.

Thus, the various signals for the “0” write operation are generated.

Note that when the “0” write operation is terminated, the “H”-level signal WDIS inverted by the inverter INV4 is temporarily output, in the same manner as when the “1” write operation is terminated. In addition, the “H”-level signal WRTb is output. Consequently, the clamp signal Vclamp changes to “L” level.

Also, since the signal WRT0 changes to “L” level, the sense enable signals SEN1 and SEN2 change to “L” level. Accordingly, the sense amplifier 30 is initialized.

### Effects of First Embodiment

In the above-mentioned first embodiment, the MRAM includes the current detection type sense amplifier 30 electrically connected to one side of the memory cell array 10 (the memory cell MC), and the write driver 70 electrically connected to the other side. In addition, the MRAM includes the write clamp voltage generator 60 which outputs an “H”-level or “L”-level signal to the gate of the clamp transistor M4 arranged between the sense amplifier 30 and memory cell MC. By controlling these circuits, a write current using a portion of the sense amplifier 30 and a portion of the write driver 70 as current paths is generated, and a write operation to a memory cell is performed.

This makes it possible to reduce a write driver, which is normally necessary, on one side (the sense amplifier 30 side) of the memory cell MC. More specifically, one write driver 70 need only be formed for the memory cell array 10 which is driven by one sense amplifier 30. As a result, the circuit area and chip size can be reduced.

### Second Embodiment

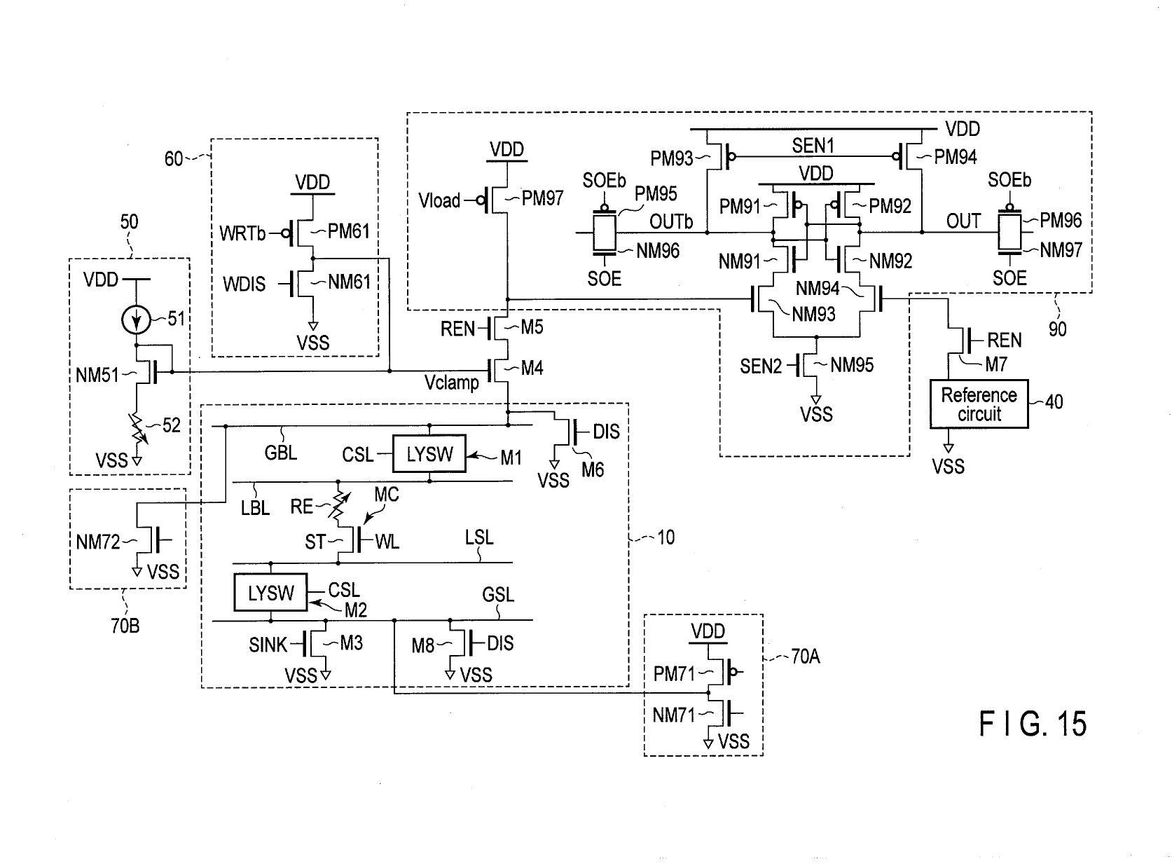

A semiconductor memory device according to the second embodiment will be explained below with reference to FIGS. 15, 16, and 17. In the first embodiment, the current paths for the write operation are formed by using the current detection type sense amplifier 30. By contrast, the second embodiment is an example in which the current paths for the write operation are formed by using a voltage detection type sense amplifier 90. Details of the second embodiment will be explained below.

Note that in the second embodiment, an explanation of the same features as those of the above-mentioned first embodiment will be omitted, and differences will mainly be explained.

### Arrangement and Operation of Second Embodiment

The arrangement and operation of the semiconductor memory device according to the second embodiment will be explained with reference to FIGS. 15, 16, and 17.

### (Arrangement)

The arrangement of the semiconductor memory device according to the second embodiment will be explained below.

FIG. 15 is a schematic view showing each constituent element according to the second embodiment. Note that FIG. 15 do not illustrate a word line driver 20 and controller 80. Note also that only one memory cell MC is shown in a memory cell array 10.

As shown in FIG. 15, the second embodiment differs from the first embodiment in that the sense amplifier 90 is a voltage detection type circuit, and not only a first write driver 70A but also a second write driver 70B is arranged.

A reference circuit 40 includes a reference cell in which data “1” is stored, and a reference cell in which data “0” is stored. By using these reference cells, the reference circuit 40 generates a reference current intermediate between data “1” and data “0”. The reference circuit 40 is electrically connected to the second input terminal of the sense amplifier 90 via an NMOS transistor (read enable transistor) M7.

The sense amplifier 90 is electrically connected to one side (a global bit line GBL side) of the memory cell array 10. More specifically, the sense amplifier 90 has a first input terminal electrically connected to a global bit line GBL (one side) via the current path of a read enable transistor M5 and the current path of a clamp transistor M4, and a second input terminal electrically connected to the reference circuit 40 via the current path of the NMOS transistor M7. The sense amplifier 90 is a voltage detection type sense amplifier.

The first write driver 70A is electrically connected to a global source line GSL (the other side) of the memory cell array 10. A write current flows out from or flows into the first write driver 70A.

The second write driver 70B is electrically connected to the global bit line GBL (one side) of the memory cell array 10. A write current flows into the second write driver 70B.

Details of the sense amplifier 90, first write driver 70A, and second write driver 70B will be explained below.

The sense amplifier 90 includes a first inverter, a second inverter, NMOS transistors NM93, NM94, and NM95, PMOS transistors PM93, PM94, and PM97, first pass transistors, and second pass transistors.

The first inverter includes a PMOS transistor PM91 and NMOS transistor NM91. The first inverter has a first input terminal, a first output terminal, and first and second voltage terminals. The second inverter includes a PMOS transistor PM92 and NMOS transistor NM92. The second inverter has a second input terminal, a second output terminal, and third and fourth voltage terminals.

The first voltage terminal (one terminal of the PMOS transistor PM91) and the third voltage terminal (one terminal of the PMOS transistor PM92) are electrically connected to a power supply potential terminal VDD. The second input terminal (the gates of the PMOS transistor PM92 and NMOS transistor NM92) is electrically connected to the first output terminal (the other terminal of the PMOS transistor PM91 and one terminal of the NMOS transistor NM91). The second output terminal (the other terminal of the PMOS transistor PM92 and one terminal of the NMOS transistor NM92) is electrically connected to the first input terminal (the gates of the PMOS transistor PM91 and NMOS transistor NM91).

The first pass transistors include an NMOS transistor NM96 and PMOS transistor PM95. The second pass transistors include an NMOS transistor NM97 and PMOS transistor PM96.

One end of the current path of the PMOS transistor (sense enable transistor) PM93 is electrically connected to the first output terminal of the first inverter, and the other end of the current path of the PMOS transistor PM93 is electrically connected to the power supply potential terminal VDD. One end of the current path of the PMOS transistor PM94 is electrically connected to the second output terminal of the second inverter, and the other end of the current path of the PMOS transistor PM94 is electrically connected to the power supply potential terminal VDD. A sense enable signal SEN1 is supplied to the gates of the PMOS transistors PM93 and PM94.

The first pass transistors (the NMOS transistor NM96 and PMOS transistor PM95) are electrically connected to the first output terminal of the first inverter. Output enable signals SOE and SOEb are respectively supplied to the gates of the NMOS transistor NM96 and PMOS transistor PM95. The second pass transistors (the NMOS transistor NM97 and PMOS transistor PM96) are electrically connected to the second output terminal of the second inverter. The output enable signals SOE and SOEb are respectively supplied to the gates of the NMOS transistor NM97 and PMOS transistor PM96.

One end of the current path of the NMOS transistor NM93 is electrically connected to the second voltage terminal (the other end of the current path of the NMOS transistor NM91) of the first inverter, and the other end of the current path of the NMOS transistor NM93 is electrically connected to one terminal of the NMOS transistor NM95. One end of the current path of the NMOS transistor NM94 is electrically connected to the fourth voltage terminal (the other end of the current path of the NMOS transistor NM92) of the second inverter, and the other end of the current path of the NMOS transistor NM94 is electrically connected to one terminal of the NMOS transistor NM95. The other terminal of the NMOS transistor NM95 is electrically connected to a ground potential terminal VSS. A sense enable signal SEN2 is supplied to the gate of the NMOS transistors NM95.

The gate of the NMOS transistor NM93 (i.e., the first input terminal of the sense amplifier 90) is electrically connected to one end of the current path of the read enable transistor M5 and one terminal of the PMOS transistor PM97. The other end of the current path of the read enable transistor M5 is electrically connected to one end of the current path of the clamp transistor M4. The other end of the current path of the clamp transistor M4 is electrically connected to the global bit line GBL. The other terminal of the PMOS transistor PM97 is electrically connected to the power supply potential terminal VDD. A load signal Vload is supplied to the gate of the PMOS transistor PM97.

The gate of the NMOS transistor NM94 (i.e., the second input terminal of the sense amplifier 90) is electrically connected to one end of the current path of the read enable transistor M7. The other end of the current path of the read enable transistor M7 is electrically connected to the reference circuit 40.

The first write driver 70A includes an NMOS transistor NM71 and PMOS transistor PM71. One end of the current path of the PMOS transistor PM71 is electrically connected to the power supply potential terminal VDD, and the other end is electrically connected to one end of the current path of the NMOS transistor NM71. The other end of the current path of the NMOS transistor NM71 is electrically connected to the ground potential terminal. An “H”-level or “L”-level signal is supplied to the gates of the PMOS transistor PM71 and NMOS transistor NM71. The connection terminals of the PMOS transistor PM71 and NMOS transistor NM71 (the other terminal of the PMOS transistor PM71 and one terminal of the NMOS transistor NM71) are electrically connected to the global bit line GBL.

The second write driver 70B includes an NMOS transistor NM72. One end of the current path of the NMOS transistor NM72 is electrically connected to the global bit line GBL, and the other end is electrically connected to the ground potential terminal. An “H”-level or “L”-level signal is supplied to the gate of the NMOS transistor NM72.

### (Read Operation)

A read operation of the semiconductor memory device according to the second embodiment will be explained below.

First, in a standby state before the read operation is started, the sense enable signal SEN1 is at “L” level, and the sense enable transistors PM93 and PM94 are ON. A discharge signal DIS is at “H” level, and discharge transistors M6 and M8 are ON. The load signal Vload is at “L” level, and the PMOS transistor PM97 is ON.

Also, a word line WL, a column selection signal CSL<n>, a sink signal SINK, the sense enable signal SEN2, the signal SOE, and the read enable signal REN are at “L” level, and the signal SOEb is at “H” level. Accordingly, MOS transistors connected to these signals are OFF. In addition, an analog voltage generator 50 sets a clamp signal Vclamp at “M” level as an analog signal, and the clamp transistor M4 is turned on in accordance with “M” level.

Note that a signal WRTb is at “H” level, a signal WDIS is at “L” level, and PMOS transistor PM61 and NMOS transistor NM61 are OFF. Therefore, a write clamp voltage generator 60 does not operate.

Then, in the initial state of the read operation, the sense enable signal SEN1 is at “L” level, and nodes OUT and OUTb are precharged to the power supply voltage VDD.

Also, the column selection signal CSL<n> changes to “H” level, and a local bit line LBL<n> and local source line LSL<n> are selected. In addition, the memory cell MC as a read target is selected by driving a word line WL<n>. Furthermore, the discharge signal DIS changes to “L” level, and the discharge transistors M6 and M8 are turned off. The sink signal SINK changes to “H” level, and a sink transistor M3 is turned on. The timing at which the sink transistor M3 is turned on is before a read current flows to the memory cell MC.

Also, the read enable signal REN changes to “H” level, and the read enable transistor M5 is turned on. Consequently, a read current flows from the sense amplifier 90 to the selected memory cell MC. In this state, the read current changes in accordance with data (“0” or “1”) stored in the selected memory cell MC. That is, in accordance with whether the selected memory cell MC is in the low-resistance state or high-resistance state, the read current changes, and the voltage of the connection node between the read enable transistor M5 and PMOS transistor PM97 changes. This connection-node voltage which changes in accordance with the data in the selected memory cell MC will be referred to as a cell voltage VDATA hereinafter.

Subsequently, the sense enable signal SEN1 changes to “H” level, and the sense enable transistors PM93 and PM94 are turned off. Therefore, the precharge of the nodes OUT and OUTb is stopped. In addition, the sense enable signal SEN2 changes to “H” level, and the sense enable transistors NM93 and NM94 are turned on. Accordingly, a reference voltage VREF supplied by the reference circuit 40 and the cell voltage VDATA are compared. Then, a latch circuit including the PMOS transistors PM91 and PM92 and NMOS transistors NM91 and NM92 holds “H” or “L” level in accordance with the comparison result. The “H” or “L” level (data) held in this latch circuit is output from the nodes OUT and OUTb.

Finally, the output enable signal SOE changes to “H” level, the output enable signal SOEb changes to “L” level, and the NMOS transistors NM96 and NM97 and PMOS transistors PM95 and PM96 are turned on. Consequently, the “H” or “L” level held in the latch circuit is output as output signals from the nodes OUT and OUTb.

### (Write Operation)

A write operation of the semiconductor memory device according to the second embodiment will be explained below.

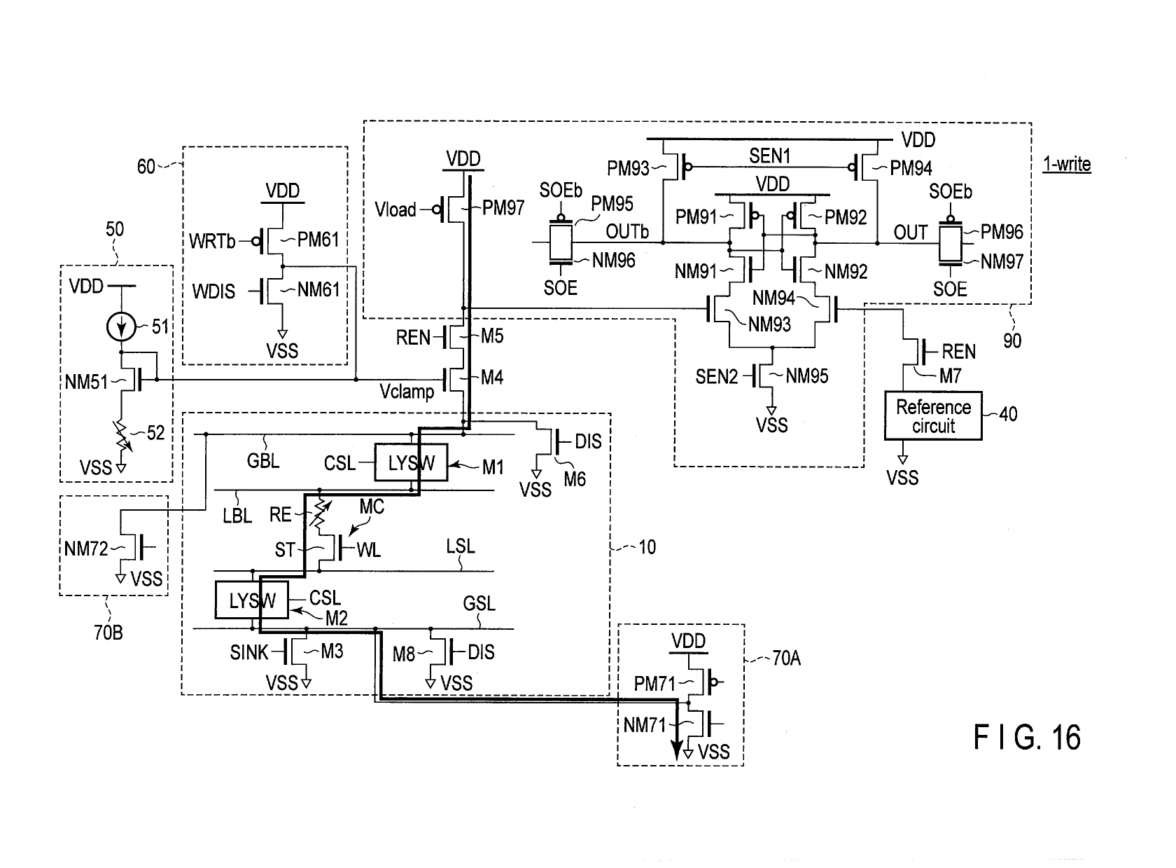

FIG. 16 is a schematic view showing a “1” write operation of the semiconductor memory device according to the second embodiment.

First, in a standby state before the “1” write operation is started, the read enable signal REN is at “L” level, and the load signal Vload is at “L” level. Accordingly, the read enable transistor M5 is OFF, and the PMOS transistor PM97 is ON.

Also, the signal WRTb is at “H” level, and the signal WDIS is at “L” level, so the PMOS transistor PM61 and NMOS transistor NM61 are OFF. The analog signal generator 50 sets the clamp signal Vclamp at “M” level. In addition, an “H”-level signal is supplied to the gate of the PMOS transistor PM71, and an “L”-level signal is supplied to the gate of the NMOS transistor NM71, so the PMOS transistor PM71 and NMOS transistor NM71 are turned off. Furthermore, an “L”-level signal is supplied to the gate of the NMOS transistor NM72, so the NMOS transistor NM72 is turned off.

In this state, the first write driver 70A, second write driver 70B, and sense amplifier 90 do not operate and are deactivated.

Then, the read enable signal REN changes to “H” level, and the read enable transistor M5 is turned on. Also, the signal WRTb changes to “L” level, and the PMOS transistor PM61 is turned on. Accordingly, the clamp signal Vclamp changes to “H” level by using the PMOS transistor PM61 as a trigger. In addition, an “H”-level signal is supplied to the gate of the NMOS transistor NM71, so the NMOS transistor NM71 is turned on.

Also, the discharge signal DIS and sink signal SINK are at “L” level, and the discharge transistors M6 and M8 and sink transistor M3 are OFF.

By holding this state for a predetermined period, as shown in FIG. 16, a “1” write current flows in a direction from the sense amplifier 90 to the first write driver 70A. More specifically, the “1” write current flows from the power supply potential terminal VDD of the sense amplifier 90 to the ground potential terminal VSS of the first write driver 70A via the PMOS transistor PM97, read enable transistor M5, clamp transistor M4, memory cell MC, and NMOS transistor NM71 in this order. As a consequence, data “1” is written to the memory cell MC.

Subsequently, after the write operation is terminated, the read enable signal REN changes to “L” level, and the read enable transistor M5 is turned off. Also, the signals WRTb and WDIS change to “H” level, so the PMOS transistor PM61 is turned off, and the NMOS transistor NM61 is turned on. Accordingly, the signal Vclamp changes to “L” level by using the NMOS transistor NM61 as a trigger. In addition, an “L”-level signal is supplied to the gate of the NMOS transistor NM71, so the NMOS transistor NM71 is turned off.

After that, the signal WDIS changes to “L” level, and the NMOS transistor NM61 is turned off. Consequently, the analog voltage generator 50 sets the signal Vclamp at “M” level, thereby setting the semiconductor memory device in the standby state.

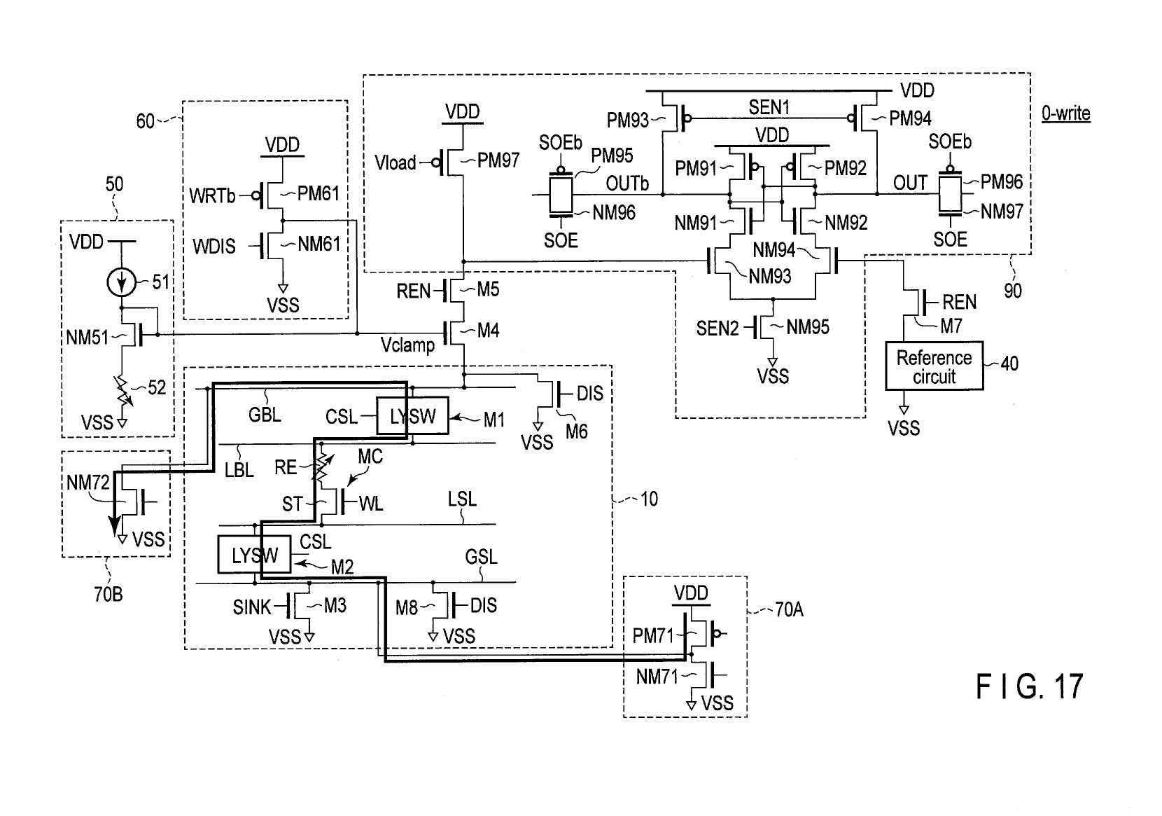

FIG. 17 is a schematic view showing a “0” write operation of the semiconductor memory device according to the second embodiment.

First, in a standby state before the “0” write operation is started, the read enable signal REN is at “L” level, and the load signal Vload is at “L” level. Accordingly, the read enable transistor M5 is OFF, and the PMOS transistor PM97 is ON.

Also, the signal WRTb is at “H” level, and the signal WDIS is at “L” level, so the PMOS transistor PM61 and NMOS transistor NM61 are OFF. The analog signal generator 50 sets the clamp signal Vclamp at “M” level. In addition, an “H”-level signal is supplied to the gate of the PMOS transistor PM71, and an “L”-level signal is supplied to the gate of the NMOS transistor NM71, so the PMOS transistor PM71 and NMOS transistor NM71 are turned off. Furthermore, an “L”-level signal is supplied to the gate of the NMOS transistor NM72, so the NMOS transistor NM72 is turned off.

In this state, the first write driver 70A, second write driver 70B, and sense amplifier 90 do not operate and are deactivated.

Then, an “L”-level signal is supplied to the gate of the PMOS transistor PM71, so the PMOS transistor PM71 is turned on. In addition, an “H”-level signal is supplied to the gate of the NMOS transistor NM72, so the NMOS transistor NM72 is turned on.

Furthermore, the discharge signal DIS and sink signal SINK are at “L” level, and the discharge transistors M6 and M8 and sink transistor M3 are OFF.

By holding this state for a predetermined period, as shown in FIG. 17, a “0” write current flows in a direction from the first write driver 70A to the second write driver 70B. More specifically, the “0” write current flows from the power supply potential terminal VDD of the first write driver 70A to the ground potential terminal VSS of the second write driver 70B via the PMOS transistor PM71, memory cell MC, and NMOS transistor NM72 in this order. As a consequence, data “0” is written to the memory cell MC.

Subsequently, after the write operation is terminated, an “H”-level signal is supplied to the gate of the PMOS transistor PM71, so the PMOS transistor PM71 is turned off. Also, an “L”-level signal is supplied to the gate of the NMOS transistor NM72, so the NMOS transistor NM72 is turned off.

### Effects of Second Embodiment

In the above-mentioned second embodiment, the MRAM includes the voltage detection type sense amplifier 90 and second write driver 70B electrically connected to one side of the memory cell array 10 (the memory cell MC), and the first write driver 70A electrically connected to the other side. In addition, the MRAM includes the write clamp voltage generator 60 which outputs an “H”-level or “L”-level signal to the gate of the clamp transistor M4 arranged between the sense amplifier 90 and memory cell MC. By controlling these circuits, a write current using a portion of the sense amplifier 90, a portion of the first write driver 70A, and a portion of the second write driver 70B as current paths is generated, and a write operation to the memory cell MC is performed.

This makes it possible to reduce a part (PMOS transistor) of the second write driver 70B, which is normally necessary, on one side (the sense amplifier 90 side) of the memory cell MC. More specifically, one first write driver 70A and one second write driver 70B including the NMOS transistor NM72 need only be formed for the memory cell array 10 which is driven by one sense amplifier 90. As a result, the circuit area and chip size can be reduced.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a memory cell including a variable resistance element;
a sense amplifier connected to one side of the memory cell; and
a write driver connected to the other side of the memory cell;
wherein a write current flows between the sense amplifier and the write driver in a write operation.

2. The device of claim 1, wherein the write current flows from the sense amplifier to the write driver in a write operation of a first logical value, and the write current flows from the write driver to the sense amplifier in a write operation of a second logical value.

3. The device of claim 1, further comprising:
a first transistor forming a current path between the sense amplifier and the memory cell.

4. The device of claim 3, further comprising a voltage generator configured to supply a voltage at which the first transistor is turned on to a gate of the first transistor in a write operation.

5. The device of claim 4, wherein in a write operation, the voltage generator supplies a voltage at which the first transistor is turned on to the gate of the first transistor, and supplies a voltage at which the first transistor is turned off to the gate of the first transistor thereafter.

6. The device of claim 4, wherein the voltage generator includes:
a second transistor having one terminal connected to a power supply potential terminal, and the other terminal connected to the gate of the first transistor; and
a third transistor having one terminal connected to the gate of the first transistor, and the other terminal connected to a ground potential terminal.

7. The device of claim 6, wherein in a write operation, a voltage at which the second transistor is turned on and the third transistor is turned off is supplied to a gate of the second transistor and a gate of the third transistor, and a voltage at which the second transistor is turned off and the third transistor is turned on is supplied to the gate of the second transistor and the gate of the third transistor thereafter.

8. The device of claim 6, further comprising a fourth transistor forming a current path between the sense amplifier and the first transistor,
wherein in a write operation, a voltage at which the fourth transistor is turned on is supplied to a gate of the fourth transistor, and a voltage at which the fourth transistor is turned off is supplied to a gate of the fourth transistor thereafter.

9. The device of claim 1, further comprising a controller including:
a first inverter to which a read command is input;
a second inverter to which a write command is input;
a first NAND gate to which an output signal from the first inverter and an output signal from the second inverter are input;
a delay circuit to which the output signal from the second inverter is input;
a third inverter to which an output signal from the delay circuit is input;
a second NAND gate to which the output signal from the second inverter and an output signal from the third inverter are input; and
a fourth inverter to which an output signal from the second NAND gate is input.

10. The device of claim 1, wherein the sense amplifier is a current detection type sense amplifier.

11. The device of claim 1, wherein the write driver includes:
a fifth transistor having one terminal connected to a power supply potential terminal, and the other terminal connected to the other side of the memory cell; and
a sixth transistor having one terminal connected to the other side of the memory cell, and the other terminal connected to a ground potential terminal.

12. The device of claim 1, further comprising a reference circuit configured to generate a reference signal,
wherein the sense amplifier has a first input terminal connected one side of the memory cell, and a second input terminal connected to the reference circuit.

13. A semiconductor memory device comprising:
a memory cell including a variable resistance element;
a sense amplifier connected to one side of the memory cell;
a write driver connected to the other side of the memory cell;
a first transistor forming a current path between the sense amplifier and the memory cell; and
a voltage generator configured to supply a voltage at which the first transistor is turned on to a gate of the first transistor.

14. The device of claim 13, wherein a write current flows between the sense amplifier and the write driver in a write operation.

15. The device of claim 13, wherein the write current flows from the sense amplifier to the write driver in a write operation of a first logical value, and the write current flows from the write driver to the sense amplifier in a write operation of a second logical value.

16. The device of claim 13, wherein in a write operation, the voltage generator supplies a voltage at which the first transistor is turned on to the gate of the first transistor, and supplies a voltage at which the first transistor is turned off to the gate of the first transistor thereafter.

17. The device of claim 13, wherein the voltage generator includes:
a second transistor having one terminal connected to a power supply potential terminal, and the other terminal connected to the gate of the first transistor; and
a third transistor having one terminal connected to the gate of the first transistor, and the other terminal connected to a ground potential terminal.

18. The device of claim 17, wherein in a write operation, a voltage at which the second transistor is turned on and the third transistor is turned off is supplied to a gate of the second transistor and a gate of the third transistor, and a voltage at which the second transistor is turned off and the third transistor is turned on is supplied to the gate of the second transistor and the gate of the third transistor thereafter.

19. The device of claim 17, further comprising a fourth transistor forming a current path between the sense amplifier and the first transistor,
wherein in a write operation, a voltage at which the fourth transistor is turned on is supplied to a gate of the fourth transistor, and a voltage at which the fourth transistor is turned off is supplied to a gate of the fourth transistor thereafter.

20. A semiconductor memory device comprising:
a memory cell including a variable resistance element;
a sense amplifier connected to one side of the memory cell;
a first write driver connected to the other side of the memory cell; and
a second write driver connected to one side of the memory cell,
wherein a write current flows between the sense amplifier and the first write driver, or the first write driver and the second write driver in a write operation.
